(19) United States
(12) Patent Application Publication
(10) Pub. No.: US 2023/0015154 A1
(43) Pub. Date: Jan. 19, 2023

(54) FE-BASED ALLOY AND ELECTRONIC COMPONENT INCLUDING THE SAME

(71) Applicant: SAMSUNG ELECTRO-MECHANICS CO., LTD., Suwon-si (KR)

(72) Inventors: Sang Kyun Kwon, Suwon-si (KR); Chul Min Sim, Suwon-si (KR); Han Wool Ryu, Suwon-si (KR); Byeong Cheol Moon, Suwon-si (KR)

(73) Assignee: SAMSUNG ELECTRO-MECHANICS CO., LTD., Suwon-si (KR)

(21) Appl. No.: 17/736,347

(22) Filed: May 4, 2022

(30) Foreign Application Priority Data
Jul. 6, 2021 (KR) 10-2021-0088594

(51) Int. Cl. C22C 38/10; C22C 38/14; C22C 38/12; C22C 38/08; C22C 38/02; C22C 38/00; H01F 1/153; H01F 27/255

(52) U.S. Cl. CPC C22C 38/10; C22C 38/14; C22C 38/12; C22C 38/08; C22C 38/02; C22C 38/002; H01F 1/15333; H01F 1/15308; H01F 27/255; C22C 2202/02; C22C 2200/04

(57) ABSTRACT

A Fe-based alloy represented by a composition of (Fe₍₁₋ₐ₎M¹ₐ)_{100-b-c-d-e-f-g}M²_{b}M³_{c}B_{d}PₑCu_{f}Ti_{g}, wherein M¹ is at least one element selected from the group consisting of Co and Ni, M² is at least one element selected from the group consisting of Nb, Mo, Zr, Ta, W, Hf, Ti, V, Cr, and Mn, M³ is at least one element selected from the group consisting of Si, Al, Ga, and Ge, and a, b, c, d, e, f, and g satisfy the following content conditions: 0≤a≤0.5, 0<b≤1.5, 0<c≤4, 7≤d≤13, 0.1≤e≤5, 0.6≤f≤1.5, and 0<g, is provided, wherein a full width at half maximum of an XRD main peak is 0.172 or more.

### CROSS-REFERENCE TO RELATED APPLICATION(S)

This application claims benefit of priority to Korean Patent Application No. 10-2021-0088594 filed on Jul. 6, 2021 in the Korean Intellectual Property Office, the disclosure of which is incorporated herein by reference in its entirety.

### TECHNICAL FIELD

The present disclosure relates to a Fe-based alloy and an electronic component including the same.

### BACKGROUND

In the technical field of devices such as inductors, transformers, motor magnetic cores, and wireless power transmission devices, soft magnetic materials having improved miniaturization and high frequency properties have been developed, and recently, an Fe-based nanocrystal alloy has been attracting attention.

The Fe-based nanocrystal alloy has a high magnetic permeability and twice or more a saturated magnetic flux density of conventional ferrite and operates at high frequencies as compared with conventional metals. However, since performance limits thereof have recently emerged, a new Fe-based alloy composition for improving a saturated magnetic flux density is being developed. However, generally, when the saturated magnetic flux density is improved, amorphous properties of the alloy may be lowered.

### SUMMARY

An aspect of the present disclosure may provide a Fe-based alloy which has excellent amorphous properties of a parent phase to have a high saturated magnetic flux density and has a low loss and an electronic component using the same. The Fe-based alloy facilitates production of nanocrystal grains even in a powder form and has excellent magnetic properties such as a saturated magnetic flux density.

According to an aspect of the present disclosure, a novel Fe-based alloy may be represented by a composition of (Fe₍₁₋ₐ₎M¹ₐ)_{100-b-c-d-e-f-g}M²_{b}M³_{c}B_{d}PₑCu_{f}Ti_{g}, wherein M¹ is at least one element selected from the group consisting of Co and Ni, M² is at least one element selected from the group consisting of Nb, Mo, Zr, Ta, W, Hf, Ti, V, Cr, and Mn, M³ is at least one element selected from the group consisting of Si, Al, Ga, and Ge, and a, b, c, d, e, f, and g satisfy the following content conditions: 0≤a≤0.5, 0<b≤1.5, 0<c≤4, 7≤d≤13, 0.1≤e≤5, 0.6≤f≤1.5, and 0<g, wherein a full width at half maximum of an XRD main peak is 0.172 or more.

In an exemplary embodiment, the composition may satisfy a condition of 0<g<0.005.

In an exemplary embodiment, in the composition, a content of Fe may be 78 mol % or more.

In an exemplary embodiment, in the composition, the content of Fe may be 84 mol % or more.

In an exemplary embodiment, the Fe-based alloy may have a saturated magnetic flux density of 1.6 T or more.

In an exemplary embodiment, the composition may satisfy the condition of 0<g<0.005, and the Fe-based alloy may have the saturated magnetic flux density of 1.6 T or more.

In an exemplary embodiment, the composition may satisfy the condition of 0<g≤0.005.

In an exemplary embodiment, the composition may satisfy the condition of 7≤d≤9.

In an exemplary embodiment, the composition may satisfy the condition of 0.5≤c≤4.

In an exemplary embodiment, M³ may include Si.

In an exemplary embodiment, M² may include Nb.

According to another aspect of the present disclosure, an electronic component may include a coil unit, and a body covering the coil unit and including an insulator and a plurality of magnetic particles dispersed in the insulator, wherein the magnetic particles include a Fe-based alloy, the Fe-based alloy being represented by a composition of (Fe₁₋ₐ₎M¹ₐ)_{100-b-c-d-e-f-g}M²_{b}M³_{c}B_{d}PₑCu_{f}Ti_{g}, wherein M¹ is at least one element selected from the group consisting of Co and Ni, M² is at least one element selected from the group consisting of Nb, Mo, Zr, Ta, W, Hf, Ti, V, Cr, and Mn, M³ is at least one element selected from the group consisting of Si, Al, Ga, and Ge, and a, b, c, d, e, f, and g satisfy the following content conditions: 0≤a≤0.5, 0<b≤1.5, 0<c≤4, 7≤d≤13, 0.1≤e≤5, 0.6≤f≤1.5, and 0<g, and having a full width at half maximum of an XRD main peak of 0.172 or more.

In an exemplary embodiment, the composition may satisfy a condition of 0<g<0.005.

In an exemplary embodiment, in the composition, a content of Fe may be 78 mol % or more.

In an exemplary embodiment, in the composition, the content of Fe may be 84 mol % or more.

In an exemplary embodiment, the plurality of magnetic particles may have D₅₀ of 20 μm or more.

In an exemplary embodiment, the Fe-based alloy may have a saturated magnetic flux density of 1.6 T or more.

In an exemplary embodiment, the composition may satisfy the condition of 0<g<0.005, and the Fe-based alloy may have the saturated magnetic flux density of 1.6 T or more.

In an exemplary embodiment, a support substrate which is disposed in the body and supports the coil unit may be further included.

In an exemplary embodiment, the coil unit may include a winding type coil.

### BRIEF DESCRIPTION OF DRAWINGS

The above and other aspects, features and other advantages of the present disclosure will be more clearly understood from the following detailed description taken in conjunction with the accompanying drawings, in which:

FIG. 1 is a schematic perspective view showing a coil component according to an exemplary embodiment in the present disclosure.

FIG. 2 is a cross-sectional view taken along line I-I′ of FIG. 1.

FIG. 3 is an enlarged view of a body area in the coil component of FIG. 2.

FIG. 4 is a schematic perspective view showing a coil component according to another exemplary embodiment in the present disclosure.

### DETAILED DESCRIPTION

Hereinafter, exemplary embodiments in the present disclosure will now be described in detail with reference to the accompanying drawings. However, the exemplary embodiments in the present disclosure may be modified in many different forms and the scope of the disclosure should not be limited to the embodiments set forth herein. In addition, the exemplary embodiments in the present disclosure are provided so that the disclosure will be conveyed more completely to those skilled in the art. Therefore, the shapes, dimensions and the like of components in the drawings may be exaggerated for clarity, and the same reference numerals will be used throughout to designate the same or like components.

In addition, parts not related to the description are omitted in the drawings for clarity of the present disclosure, the thickness is shown to be expanded for clear expression of various layers and regions, and the elements having the same function within the same range of the concept are described using the same reference numerals. Furthermore, throughout the present specification, unless explicitly described to the contrary, “comprising” any elements will be understood to imply further inclusion of other elements rather than the exclusion of any other elements.

Electronic Component

Hereinafter, the electronic component according to an exemplary embodiment in the present disclosure will be described, and a coil component was selected as a representative example. However, a Fe-based alloy described later may also be applied to the electronic components other than the coil component, for example, a wireless charger, a filter, and the like, of course.

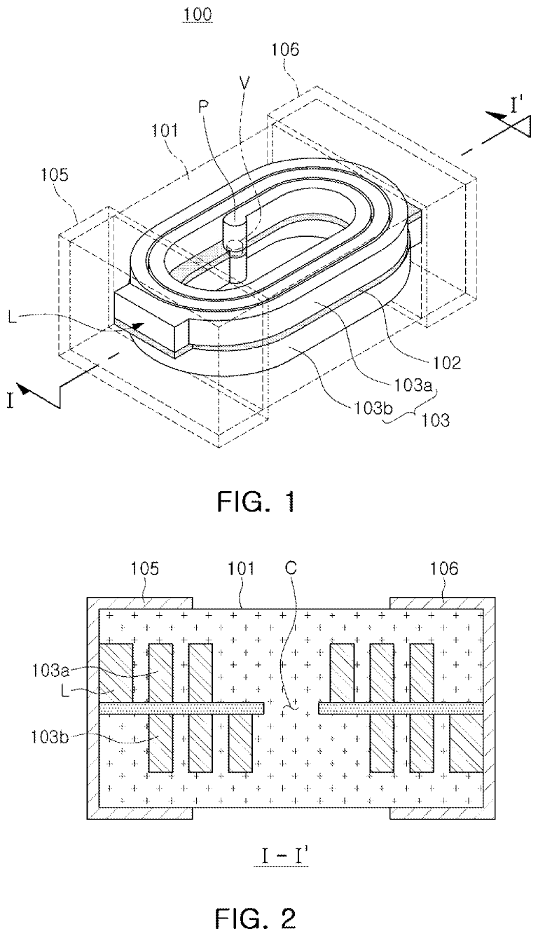

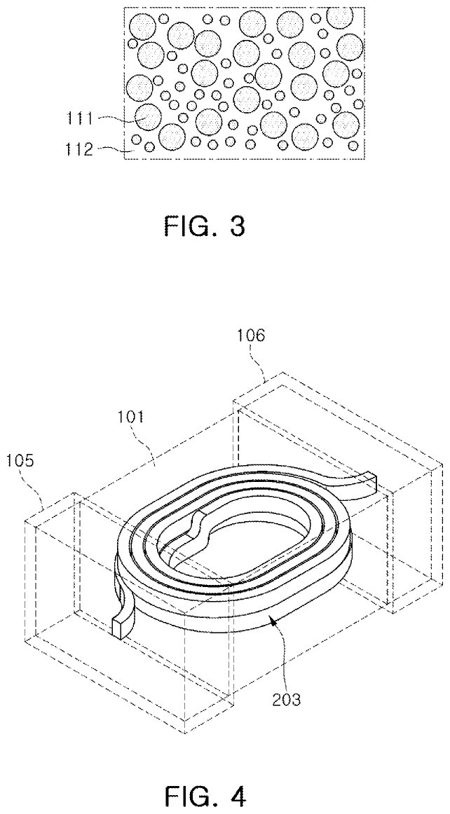

FIG. 1 is a perspective view schematically showing an appearance of the coil component of an exemplary embodiment in the present disclosure. In addition, FIG. 2 is a cross-sectional view taken along line I-I′ of FIG. 1. FIG. 3 is an enlarged view of a body area in the coil component of FIG. 2. Further, FIG. 4 is a schematic perspective view showing a coil component according to another exemplary embodiment in the present disclosure.

First, referring to FIGS. 1 and 2, a coil component 100 according to an exemplary embodiment in the present disclosure mainly includes a body 101, a support substrate 102, a coil unit 103, and external electrodes 105 and 106, and the body 101 includes a plurality of magnetic particles 111.

The body 101 covers and protects a coil unit 103, and as illustrated in FIG. 3, may include a plurality of magnetic particles 111. Specifically, the magnetic particles 111 may be in the form of being dispersed in an insulator 112 formed of a resin and the like. In this case, the magnetic particles 111 may be formed by including a Fe-based alloy, and a specific composition thereof will be described later. When the Fe-based alloy having the composition suggested in the present exemplary embodiment is used, the size, the phase, and the like of nanocrystal grains are appropriately controlled even in the case of manufacturing the alloy in the form of relatively large powder, and thus, magnetic properties appropriate for use in an inductor are shown.

The support substrate 102 supports the coil unit 103, and may be formed of a polypropylene glycol (PPG) substrate, a ferrite substrate, a metal-based soft magnetic substrate, or the like. As illustrated, a center part of the support substrate 102 is penetrated to form a through hole, and the through hole may be filled with the body 101 to form a magnetic core unit C.

The coil unit 103 is installed inside the body 101 and serves to perform various functions in electronic devices by the characteristics expressed from the coil of a coil electronic component 100. For example, the coil electronic component 100 may be a power inductor, and in this case, the coil unit 103 stores electricity in the form of a magnetic field, thereby maintaining output voltage to stabilize the power. In this case, a coil pattern forming the coil unit 103 may be in the form of being laminated on both surfaces of the support substrate 102, respectively, and may be electrically connected through a conductive via V penetrating the support substrate 102. The coil unit 103 may be formed in a spiral shape, and in the outermost portion of the spiral shape, a leading portion L which is exposed to the outside of the body 101 for an electrical connection with the external electrodes 105 and 106 may be included.

The coil unit 103 is disposed on at least one of a first surface (upper surface with reference to FIG. 2) and a second surface (lower surface with reference to FIG. 2) which face each other on the support substrate 102. As in the present exemplary embodiment, the coil unit 103 may be disposed on both the first surface and the second surface of the support substrate 102, and in this case, the coil unit 103 may include a pad area P. However, unlike this, the coil unit 103 may be disposed on only one surface of the support substrate 102. Meanwhile, the coil pattern forming the coil unit 103 may be formed using a method used in the art, such as pattern plating, anisotropic plating, and isotropic plating, and a plurality of process among them may be used to form a multilayer structure.

Meanwhile, the coil unit may be provided in the form other than the form illustrated in FIG. 1, and for example, a coil unit 203 may be implemented in a winding type as in the exemplary embodiment illustrated in FIG. 4. In this case, the support substrate supporting the coil unit 203 may not be disposed inside the body 101. The coil unit 203 may be a winding coil formed by winding a metal wire such as copper wire (Cu-wire) including a metal line and a coating layer which coats the surface of a metal wire. Therefore, the entire surface of each of a plurality of turns of the coil unit 203 may be coated with a coating layer. Meanwhile, the metal wire may be a flat wire, but is not limited thereto. When the coil unit 203 is formed of a flat wire, a cross section of each turn of the coil unit 203 may be in a rectangular shape. The coating layer may include epoxy, polyimide, liquid crystal polymer, and the like alone or in combination, but is not limited thereto.

The external electrodes 105 and 106 may be formed in the outside of the body 101 to be connected to the leading portion L. The external electrodes 105 and 106 may be formed using a paste including a metal having excellent electrical conductivity, and the paste may be, for example, a conductive paste including nickel (Ni), copper (Cu), tin (Sn), or silver (Ag) alone, or an alloy thereof. In addition, a plating layer (not shown) may be further formed on the external electrodes 105 and 106. In this case, the plating layer may include any one or more selected from the group consisting of nickel (Ni), copper (Cu), and tin (Sn), and for example, a nickel (Ni) layer and a tin (Sn) layer may be sequentially formed.

As described above, in the present exemplary embodiment, the magnetic particles 111 include a Fe-based alloy having excellent magnetic properties when manufactured in the form of powder, and hereinafter, the characteristics of the alloy will be described in detail. However, the Fe-based alloy described later may be used as a thin metal plate and the like, in addition to the powder form. In addition, the alloy may be used for a transformer, a motor magnetic core, an electromagnetic wave shielding sheet, and the like, in addition to an inductor.

Fe-Based Alloy

According to the present inventor's research, when a Fe-based alloy having a specific composition is manufactured into particles having a relatively large diameter or a metal ribbon form having a large thickness, a parent phase has high amorphous properties. The range of an alloy composition having excellent amorphous performance and saturated magnetic flux density of a parent phase was confirmed, and, in particular, the amorphous properties and the saturated magnetic flux density were improved as compared with a conventional alloy by adding Cu and Ti and appropriately adjusting the contents. Here, the particles having a relatively large diameter may be defined as particles having D₅₀ of about 20 μm, and for example, corresponds to magnetic particles 111 having D₅₀ of about 20 to 40 μm. The diameter of the magnetic particles 111 may be obtained, for example, from a circle-equivalent diameter obtained by taking the cross section of an inductor body or the like with an optical microscope and calculating the area of the magnetic particles 111. A diameter distribution of the thus-obtained magnetic particles 111 is determined, and then the D₅₀ value may be obtained, and in this case, the cross section of the inductor body and the like may be sampled in a plurality of areas. In addition, when the alloy is manufactured into a metal ribbon form, it corresponds to a case of having a diameter of about 20 μm or more, and diameter or thickness standards are not absolute and may change depending on the situation.

When the alloy having high amorphous properties is heat treated, the size of nanocrystal grains may be effectively controlled. Specifically, the Fe alloy is represented by a composition of (Fe₍₁₋ₐ₎M¹ₐ)_{100-b-c-d-e-f-g}M²_{b}M³_{c}B_{d}PₑCu_{f}Ti_{g}, wherein M¹ is at least one element selected from the group consisting of Co and Ni, M² is at least one element selected from the group consisting of Nb, Mo, Zr, Ta, W, Hf, Ti, V, Cr, and Mn, M³ is at least one element selected from the group consisting of Si, Al, Ga, and Ge, and a, b, c, d, e, f, and g mean mol % and satisfy the following content conditions: 0≤a≤0.5, 0<b≤1.5, 0<c≤4, 7≤d≤13, 0.1≤e≤5, 0.6≤f≤1.5, and 0<g. The parent phase of the Fe-based alloy having the composition may have an amorphous single phase structure (or mostly amorphous single phase structure), and after the heat treatment, the nanocrystal grain size may be effectively controlled. In the present exemplary embodiment, XRD analysis results were suggested as a standard for determining whether the size of nanocrystal grains is effectively controlled, and as described later, as a result of XRD analysis of the crystal grains of the Fe-based alloy, it was confirmed that when the full width at half maximum (FWHM) of a main peak is about 0.172 or more, the nanocrystal grains are easily produced and magnetic properties such as a saturated magnetic flux density are excellent. The main peak may be the peak having the highest intensity among the peaks in the XRD spectrum, and the full width at half maximum may be determined using the XRD spectrum processing software.

In this case, the amorphous properties of a parent phase are greatly influenced by the contents of Cu and Ti, and, in particular, it was found that the influence is increased in the Fe-based alloy having a higher Fe ratio for increasing the saturated magnetic flux density as in the present exemplary embodiment. It is preferred that the Ti content satisfies the condition of 0<g<0.005 in the composition. Further, the Fe-based alloy having a high Fe ratio corresponds to a case having a Fe content of 78 mol % or more in the composition, and the Fe-based alloy having a higher Fe ratio corresponds to a case having a Fe content of 84 mol % or more.

A Cu component contained in the Fe-based alloy may serve as a seed to lower nuclear production energy by the heat treatment when forming Fe nanocrystal grains. When the amount of Cu added is small, the nanocrystal grains may not be sufficiently produced, and herein, the content of Cu to sufficiently produce the nanocrystal grains is 0.6 mol % or more in the Fe-based alloy (that is, f≤0.6). Further, when the content of Cu is more than 1.5 mol %, Cu clusters have a nature of joining each other and increasing, and thus, since the entire area of Cu clusters is decreased, the number of α-Fe nuclei produced may be decreased. In the case of Ti, when the content of Fe is high, for example, the content of Fe is limited to 78 mol % or more and 0.005 mol % or less in the composition (that is, 0<g≤0.005), the amorphous performance of a parent phase may be improved, and when the content is higher than this, a crystal structure such as Fe-B-based or α-Fe-based is precipitated in the parent phase, thereby lowering the amorphous performance.

Hereinafter, the experimental results of the present inventors will be described in detail. The following Tables 1 and 2 show the compositions of the comparative examples and the examples used in the experiment, and the crystallinity of the parent phase before the heat treatment of the alloy obtained therefrom, and also, the full width at half maximum and the saturated magnetic flux density (Bs) were measured and are shown. For example, the saturated magnetic flux density was measured using a vibrating sample magnetometer in a magnetic field of 1000 kA/m. In the following experimental example, the content of each element is expressed as mol %, and Samples 6, 9, and 12 marked with * correspond to the examples of the present disclosure, and the other samples correspond to the comparative examples.

TABLE 1

| | | | | | | | | | Full width | |
|---|---|---|---|---|---|---|---|---|---|---|
| | | | | | | | | | at half | Bs |
| | Fe | Si | B | P | Nb | Cu | Ti | Parent phase | maximum (2θ) | (T) |
| Sample 1 | 85.300 | 0.5 | 9 | 4 | 1 | 0.1 | 0.1 | Crystalline | 0.086 | 1.73 |
| | | | | | | | | (Fe-B) | | |
| Sample 2 | 85.390 | 0.5 | 9 | 4 | 1 | 0.1 | 0.01 | Crystalline | 0.109 | 1.74 |
| | | | | | | | | (Fe-B) | | |
| Sample 3 | 85.395 | 0.5 | 9 | 4 | 1 | 0.1 | 0.005 | Crystalline | 0.172 | 1.73 |
| | | | | | | | | (Fe-B) | | |
| Sample 4 | 84.800 | 0.5 | 9 | 4 | 1 | 0.6 | 0.1 | Crystalline | 0.157 | 1.72 |
| | | | | | | | | (Fe-B) | | |
| Sample 5 | 84.890 | 0.5 | 9 | 4 | 1 | 0.6 | 0.01 | Crystalline | 0.345 | 1.73 |
| | | | | | | | | (α-Fe) | | |
| Sample 6* | 84.895 | 0.5 | 9 | 4 | 1 | 0.6 | 0.005 | Amorphous | 4.9 | 1.68 |
| Sample 7 | 84.400 | 0.5 | 9 | 4 | 1 | 1.0 | 0.1 | Crystalline | 0.172 | 1.72 |
| | | | | | | | | (Fe-B) | | |
| Sample 8 | 84.490 | 0.5 | 9 | 4 | 1 | 1.0 | 0.01 | Crystalline | 0.43 | 1.73 |
| | | | | | | | | (α-Fe) | | |
| Sample 9* | 84.495 | 0.5 | 9 | 4 | 1 | 1.0 | 0.005 | Amorphous | 5.0 | 1.68 |

From the above experimental results, in Samples 1 to 3 having a relatively low Cu content (0.1 mol %), crystal grains were formed in the parent phase regardless of a change in the Ti content, and thus, it was difficult for the nanocrystal grains to be effectively formed even after a heat treatment. In addition, in the samples having an increased Cu content, it was confirmed that the parent phase had an amorphous single phase structure when the Ti content was limited to a level of 0.005 mol %. The following Table 2 shows an experimental example in the same manner as in Table 1, using a Fe-based alloy having a lower Fe content than in Table 1. Even in the Fe-based alloy having a Fe content of 78 mol %, when a Cu content was 1 mol %, it was confirmed that the parent phase had amorphous single phase structure when a Ti content was limited to a level of 0.005 mol %.

TABLE 2

| | | | | | | | | | Full width | |
|---|---|---|---|---|---|---|---|---|---|---|
| | | | | | | | | | at half | Bs |
| | Fe | Si | B | P | Nb | Cu | Ti | Parent phase | maximum (2θ) | (T) |
| Sample 10 | 77.9 | 3 | 12 | 5 | 1 | 1 | 0.1 | Crystalline | 0.172 | 1.62 |
| | | | | | | | | (Fe-B) | | |
| Sample 11 | 77.99 | 3 | 12 | 5 | 1 | 1 | 0.01 | Crystalline | 0.431 | 1.63 |
| | | | | | | | | (α-Fe) | | |
| Sample 12* | 77.995 | 3 | 12 | 5 | 1 | 1 | 0.005 | Amorphous | 4.85 | 1.6 |

As described above, the results shown in Tables 1 and 2 show that the Fe-based alloy to which Cu and Ti were added at specific contents had excellent amorphous properties of the parent phase, and may effectively form nanocrystal grains after the heat treatment therefrom. That is, in the case of the samples of which the parent phase was formed amorphous (Samples 6, 9, and 12), nanocrystal grains were effectively formed after the heat treatment, and as a result of XRD analysis, when the full width at half maximum of the main peak was about 0.172 or more, the nanocrystal grains were easily produced, while the magnetic properties such as the saturated magnetic flux density were excellent. The Fe-based alloy as such had excellent magnetic permeability and saturated magnetic flux density (about 1.6 T or more), and furthermore, had improved core loss properties. The saturated magnetic flux density affects DC bias properties in soft magnetism and when it has a high level of saturated magnetic flux density, it is appropriate for use in an inductor operating at a high current. Here, the saturated magnetic flux density may be measured, for example, by two methods. First, Ms of alloy powder is measured using a vibrating sample magnetometer or the like and then is substituted into a relation between Ms and Bs of B=H+4πM. As another method, the saturated magnetic flux density may be measured using a B-H tracer, and in this case, Bs may be directly measured, but measurement in a powder form is impossible, and thus, molding into a toroidal shape is needed. Generally, in order to evaluate the properties of powder, a binder having electrical insulation properties is used to manufacture a sample and Bs may be measured when evaluation is performed without the content of the binder.

Hereinafter, the main elements other than Fe, Cu, and Ti among the elements forming the Fe-based alloy will be described.

Niobium (Nb) is an element for controlling a size of nanocrystal grains, and serves to limit the crystal grains so that the crystal grains formed in a nano size such as Fe do not grow by diffusion. Generally, the content of Nb was optimized to about 3 mol %, but in the experiment carried out by the present inventors, alloy formation was attempted at a lower Nb content state than a conventional Nb content due to an increased Fe content, and as a result, nanocrystal grains were formed even at a state of lower than 3 mol %, and, in particular, unlike a general technology in which an increased content of Nb is needed by an increased content of Fe, rather, it was confirmed that the magnetic properties were improved at a lower Nb content than the conventional Nb content, in a composition range in which the Fe content was high and the crystallization energy of the nanocrystal grains was formed as a bimodal shape. Rather, it was confirmed that when the Nb content was high, the magnetic permeability which is magnetic properties was decreased and the loss was increased. In the present exemplary embodiment, b which corresponds to a mol % as the content of a M² component including Nb satisfied the condition of 0<b≤1.5.

Silicon (Si) has a function similar to B and is an element for stabilizing amorphous phase formation, as an element for forming amorphism. However, unlike B, Si is alloyed with a ferromagnetic body such as Fe even at a temperature at which the nanocrystals are formed, thereby decreasing a magnetic loss, but heat produced in nanocrystallization is increased. In particular, in the composition having a high Fe content, it was confirmed from the research results of the present inventors that it is difficult to control the size of nanocrystals. In the present exemplary embodiment, c which corresponds to a mol % as the content of a M³ component including Si satisfied the condition of 0<c≤4.

Boron (B) is a main element for forming amorphism and an element for stabilizing amorphous phase formation. B raises a temperature at which Fe and the like are crystallized into nanocrystals and has high energy of being alloyed with Fe and the like which determines magnetic properties, and thus, it is not alloyed in the process of forming nanocrystals. Therefore, it is necessary to add B to the Fe-based alloy. However, when the B content is excessively high, nanocrystallization is difficult and the saturated magnetic flux density is lowered. In the present exemplary embodiment, d which corresponds to a mol % as the content of B included in the Fe-based alloy satisfied the condition of 7≤d≤13.

Phosphorus (P) is an element for improving amorphism and amorphous properties in an alloy and is known as a metalloid with conventional Si and B. However, since P has higher bond energy with Fe, which is a ferromagnetic element, than B, when a Fe+P compound is formed, deterioration of magnetic properties is increased, and thus, commercialization has not been taken place, but recently, is being studied for securing high amorphism by developing a composition having a high saturated magnetic flux density. In the present exemplary embodiment, e which corresponds to a mol % as the content of P included in the Fe-based alloy satisfied the condition of 0.1≤e≤5.

Meanwhile, when the Fe-based alloy is used for the electronic component such as an inductor, analysis for the composition may be performed, for example, by the following process. First, an electron probe micro analyzer (EPMA) method is used as the composition analysis method of metal powder, and in the analysis method, when the cross section of the electronic component is polished and then an electron beam accelerated to about 15 to 30 kV from an electron gun collides the surface of the metal powder, X-ray having its own wavelength (energy) for each constituent element occurs, which is measured by a detector to determine the chemical composition. In this case, since an area analyzed by EPMA is a local area of the metal powder, analysis is performed on a plurality of measurement points (for example, 5 measurement points) at equal intervals on the surface of the metal powder and then an average value thereof may be used. As another analysis method, an inductively coupled plasma (ICP) method is used, in which a liquid capable of decomposing a polymer component is used to remove the polymer component from the electronic component and then a coil is removed using a physical method and the like. Thereafter, remaining metal powder is dissolved in an acid solution, and then an inductively coupled plasma atomic emission spectroscopy (ICP-AES) is used to analyze the component.

According to an exemplary embodiment in the present disclosure, a Fe-based alloy which has excellent amorphous properties of a parent phase to have a high saturated magnetic flux density and has a low loss and an electronic component using the same may be implemented. The Fe-based alloy facilitates production of nanocrystal grains even in the form of powder and has excellent magnetic properties such as a saturated magnetic flux density.

The present disclosure is not limited to the above-mentioned embodiments and the accompanying drawings, but is defined by the accompanying claims. Accordingly, various substitution, modifications and alteration may be made within the scope of the present disclosure may be made by those skilled in the art without departing from the spirit of the present disclosure defined by the accompanying claims.

While exemplary embodiments have been shown and described above, it will be apparent to those skilled in the art that modifications and variations could be made without departing from the scope of the present disclosure as defined by the appended claims.

What is claimed is:

1. A Fe-based alloy represented by a composition of (Fe₍₁₋ₐ₎M¹ₐ)_{100-b-c-d-e-f-g}M²_{b}M³_{c}B_{d}PₑCu_{f}Ti_{g},
wherein M¹ is at least one element selected from the group consisting of Co and Ni,
M² is at least one element selected from the group consisting of Nb, Mo, Zr, Ta, W, Hf, Ti, V, Cr, and Mn,
M³ is at least one element selected from the group consisting of Si, Al, Ga, and Ge, and
a, b, c, d, e, f, and g satisfy the following content conditions: 0≤a≤0.5, 0<b≤1.5, 0<c≤4, 7≤d≤13, 0.1≤e≤5, 0.6≤f≤1.5, and 0<g, and
wherein a full width at half maximum of an XRD main peak is 0.172 or more.

2. The Fe-based alloy of claim 1, wherein the composition satisfies a condition of 0<g<0.005.

3. The Fe-based alloy of claim 1, wherein in the composition, a content of Fe is 78 mol % or more.

4. The Fe-based alloy of claim 1, wherein in the composition, a content of Fe is 84 mol % or more.

5. The Fe-based alloy of claim 1, wherein the Fe-based alloy has a saturated magnetic flux density of 1.6 T or more.

6. The Fe-based alloy of claim 1, wherein the composition satisfies the condition of 0<g<0.005, and the Fe-based alloy has a saturated magnetic flux density of 1.6 T or more.

7. The Fe-based alloy of claim 1, wherein the composition satisfies the condition of 0<g≤0.005.

8. The Fe-based alloy of claim 1, wherein the composition satisfies the condition of 7≤d≤9.

9. The Fe-based alloy of claim 1, wherein the composition satisfies the condition of 0.5≤c≤4.

10. The Fe-based alloy of claim 1, wherein M³ includes Si.

11. The Fe-based alloy of claim 1, wherein M² includes Nb.

12. An electronic component comprising:
a coil unit; and
a body covering the coil unit and including an insulator and a plurality of magnetic particles dispersed in the insulator,
wherein the magnetic particles include a Fe-based alloy, the Fe-based alloy being represented by a composition of (Fe₍₁₋ₐ₎M¹ₐ)_{100-b-c-d-e-f-g}M²_{b}M³_{c}B_{d}PₑCu_{f}Ti_{g},
wherein M¹ is at least one element selected from the group consisting of Co and Ni,
M² is at least one element selected from the group consisting of Nb, Mo, Zr, Ta, W, Hf, Ti, V, Cr, and Mn,
M³ is at least one element selected from the group consisting of Si, Al, Ga, and Ge, and
a, b, c, d, e, f, and g satisfy the following content conditions: 0≤a≤0.5, 0<b≤1.5, 0<c≤4, 7≤d≤13, 0.1≤e≤5, 0.6≤f≤1.5, and 0<g, and
having a full width at half maximum of an XRD main peak of 0.172 or more.

13. The electronic component of claim 12, wherein the composition satisfies a condition of 0<g<0.005.

14. The electronic component of claim 12, wherein in the composition, a content of Fe is 78 mol % or more.

15. The electronic component of claim 12, wherein in the composition, a content of Fe is 84 mol % or more.

16. The electronic component of claim 12, wherein the plurality of magnetic particles have D₅₀ of 20 μm or more.

17. The electronic component of claim 12, wherein the Fe-based alloy has a saturated magnetic flux density of 1.6 T or more.

18. The electronic component of claim 12, wherein the composition satisfies the condition of 0<g<0.005, and the Fe-based alloy has a saturated magnetic flux density of 1.6 T or more.

19. The electronic component of claim 12, further comprising: a support substrate which is disposed in the body and supports the coil unit.

20. The electronic component of claim 12, wherein the coil unit includes a winding type coil.
